(19) United States
(12) Patent Application Publication
(10) Pub. No.: US 2007/0111404 A1
(43) Pub. Date: May 17, 2007

(54) Method of manufacturing strained-silicon semiconductor device

(75) Inventors: Yun-Hsiu Chen, Hsin-Chu (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/272,938

(22) Filed: Nov. 14, 2005

(51) Int. Cl. H01L 21/8232; H01L 21/335

(52) U.S. Cl. 438/142

(57) ABSTRACT

A method for fabricating a strained-silicon semiconductor device to ameliorate undesirable variation in epitaxial film thickness. The layout or component configuration for the proposed semiconductor device is evaluated to determine areas of relatively light or dense population in order to determine whether local-loading-effect defects are likely to occur. If a possibility of such defects occurring exists, a dummy pattern of epitaxial structures may be indicated. If so, the dummy pattern appropriate to the proposed layout is created, incorporated into the mask design, and then implemented on the substrate along with the originally-proposed component configuration.

### TECHNICAL FIELD

The present invention relates generally to a method for fabricating semiconductors, and more particularly to a method for fabricating a semiconductor device to reduce the undesirable effects of local loading while employing selective epitaxial growth (SEG) in a strained silicon fabrication.

### BACKGROUND

Electronic devices using semiconductors are utilized in a wide variety of applications. They provide the computing capability and data storage that make possible not only the operation of computers, large and small, but also things like electronic gaming devices, home entertainment systems, and telephones and other communications equipment. Advances in technology have made possible not only the construction of these and other components, but have made them more capable, more portable, and more affordable as well.

A semiconductor is actually a material that is a conductor of electricity under some conditions, but not others. Silicon, for example, may be treated with a dopant such as ionized boron or phosphorus so that its conducting capabilities may be turned on or off by the presence (or absence) of an electrical field. Small electronic components that exploit this property may be constructed. One such component is a transistor. A transistor is a small switch that can be used to control the flow of a (typically small) amount of electricity. Computers, for example, employ thousands of these tiny switches to send the electrical signals that allow them to quickly perform complex calculations.

An exemplary transistor is shown in FIG. 1. FIG. 1 is an illustration showing in cross-section the basic components of a MOSFET 10 (metal-oxide semiconductor field effect transistor). The doped silicon forms the substrate 15 upon which various devices may be fabricated. The transistor includes a gate 20 having a gate electrode 25 made of a conductive material such as a metal, and is separated from the substrate 15 by a thin gate oxide layer 30. In the transistor 10 of FIG. 1, spacers 35 are positioned on either side of the gate electrode 25. Conductive regions called a source 40 and a drain 45 are formed in the substrate 15 on either side of the spacers 35. Source 40, drain 45, and gate electrode 25 are each coupled, respectively, to electrical contacts 50, 51, 52, each of which may in turn be connected to external components (not shown) so that electrical current may flow to and from these transistor components when appropriate. When a small electrical charge is applied to gate electrode 25 via contact 52, then current will flow between drain 45 and source 40 via channel region 5. These MOSFET transistors are very small, for example, the gate electrode 25 of MOSFET 10 may be no more than 100 nm in width.

As mentioned above, thousands, or even millions of these transistors may be employed in the manufacture of even a small personal computer. Because of their small size, however, a great many transistors may be formed on a single substrate, as illustrated in FIG. 2. FIG. 2 is an illustration showing in cross-section a semiconductor device 55, which is a substrate 15 populated with a number of individual MOSFET transistors 10. Note that for convenience, all of these devices are shown to be identical, but the formation of other types of devices as well is both possible and typical (although there are usually a great many substantially-identical semiconductor devices present). The component transistors 10 in FIG. 2 being substantially identical, selected reference numbers have been applied to only one of them. As with FIG. 1, the external connections to these devices are not illustrated; some of the transistors with be connected to each other, and some to external devices (also not shown). Note also that the term ‘semiconductor device’ is being used broadly to include both a complete, fabricated unit or simply a portion of one. As should be apparent, FIG. 2 illustrates only a small portion of a complete unit.

This entire unit (not shown), once completed, is enclosed in the familiar (usually black) plastic packaging to form a chip. A number electrical leads (or pins) typically extend from the chip to facilitate connections between internal and external circuits. There are a number of process steps, however, that the semiconductor goes through prior to packaging. The processes used for fabricating semiconductor devices are both numerous and varied, but the overall methodology can be generally described.

The process typically begins with the provision of the substrate, such as substrate 15 shown in FIGS. 1 and 2. The substrate 15 is often a thin slice of silicon called a wafer. The silicon wafer then undergoes doping, followed by a series of steps in which a variety of materials are deposited or selectively etched away. In this manner, the MOSFET transistors 10 shown in FIG. 2 may be fabricated onto the surface of wafer substrate 15. Although not shown in FIG. 2, these transistors (and other devices as well) will be connected together to form circuits that perform the various functions required of the chip.

Notwithstanding the advances that have already been made, there is a constant drive in the semiconductor industry to create ever-denser collections of electronic devices on a single chip. This allows for greater functionality for the chip or permits it to be made smaller, or both. The speed of the chips operation may also be enhanced by the reducing the size of the devices formed on the wafer and placing them closer together. Components are now so small, however, that advances in speed are not necessarily resulting simply from reductions in size.

One response is to use strained silicon in the construction of semiconductor devices. Strained silicon takes advantage of a characteristic of the substrate material, namely that in certain applications silicon allows electrical-charge carriers to pass more quickly when its crystal lattice is stretched (or compressed) a small amount. In one way to accomplish this stretching, an alloy of silicon and germanium is deposited onto an existing silicon layer. On top of this silicon-germanium layer is then deposited a thin layer of silicon. The germanium in the silicon-germanium alloy causes the atoms in the overlying silicon layer to be somewhat stretched apart from their normal orientation—producing the strain of the strained silicon. One problem with using the selective epitaxial growth (SEG) strained-silicon approach is local loading. Local loading occurs where, for example, the wafer is more densely populated in one region than in another. For example, in FIG. 2, region X is a region of lower pattern density. This may, for example, be associated with an I/O function, which requires a smaller number of components than region Y, which is a higher pattern density area and may be, for example, a memory-circuit portion of the device. This tends to cause a lack of planarity when SEG is performed, a significantly undesirable condition. This can lead to local-loading-effects, such as undesirable voids forming in the source and drain regions of the more isolated transistors. FIG. 3 is an illustration of the semiconductor device 55 shown in FIG. 2 (where it is more ideally illustrated), illustrating the presence of voids 60 formed in the silicon-germanium (SiGe) source and drain regions. Void 60 may be an area of thinner SiGe or result from an incomplete SiGe deposition. These types of voids could degrade device performance, and could also serve as the defect source in subsequent process steps. Needed then is a manner of taking advantage of the benefits that the strained-silicon process SEG can produce, while at the same time avoiding its undesirable consequences, such as the source and drain voids mentioned above. The present invention provides just such a solution.

### SUMMARY OF THE INVENTION

The present invention is directed to a method of fabricating a semiconductor device using selective epitaxial growth to form portions of electrical components on a semiconductor wafer such as for the source and drain of a MOSFET. In one aspect, the present invention is a method of fabricating a semiconductor device including providing a substrate for supporting the fabrication of at least one electrical component, evaluating a proposed component layout to determine whether local-loading-effect reduction is required, if it is so determined, creating a dummy pattern for selective epitaxial growth, and implementing the dummy pattern on the substrate. The dummy pattern may include one or more recesses into which a material will be epitaxially grown, and then electrically isolated so that it reduces or eliminates local-loading-effect defects but does not interfere with operation of the semiconductor device.

In another aspect, the present invention is a semiconductor device comprising a substrate forming a first recess and at least a second recess, the first recess and the at least second recess each containing an epitaxially-grown material, the epitaxially-grown material in the first recess forming a component part of an electrical device, forming part of the originally-designed component layout, and the epitaxially-grown material in the at least second recess is electrically isolated, forming a dummy pattern according to an embodiment of the present invention.

The epitaxial regions may be formed of doped silicon or a silicon-germanium (SiGe) alloy. Carbon may also form or be included in the epitaxial-region material, for example using SiC. In one embodiment, an epitaxial material according to the formula Si_{1-X} Geₓ may be used. Different materials may, in some instances, be used for different epitaxial regions, although this is not typical. The epitaxial regions formed in recesses may, for one example, be formed on the substrate using an ultra-high vacuum chemical-vapor deposition (UHV-CVD) process. Other processes known or developed in the art may be used as well.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an illustration showing in cross-section the basic components of a MOSFET according to the prior art;

FIG. 2 is an illustration showing in cross-section a semiconductor device, which is a substrate populated with a number of individual MOSFETs such as or similar to the one illustrated in FIG. 1;

FIG. 3 is an illustration of the semiconductor device of FIG. 2, illustrating the presence of defects in the source and drain regions; and

FIGS. 4A through 4F are cross-sectional representations illustrating a semiconductor device at various stages of fabrication according to an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention. The present invention will be described with respect to preferred embodiments in a specific context, namely a semiconductor device consisting of a substrate populated with a plurality of substantially identical transistors. The invention may also be applied, however, to other semiconductor devices as well.

The present invention involves a method of manufacturing semiconductor devices. Specifically, the present invention is directed at a method of implementing selective epitaxial growth (SEG) with reduced local-loading effects in order to produce a more planar epitaxial layer. The method of the present invention will now be presented in terms of the fabrication of a semiconductor device including a plurality of transistors on a silicon wafer substrate, although this embodiment is exemplary and other applications are possible.

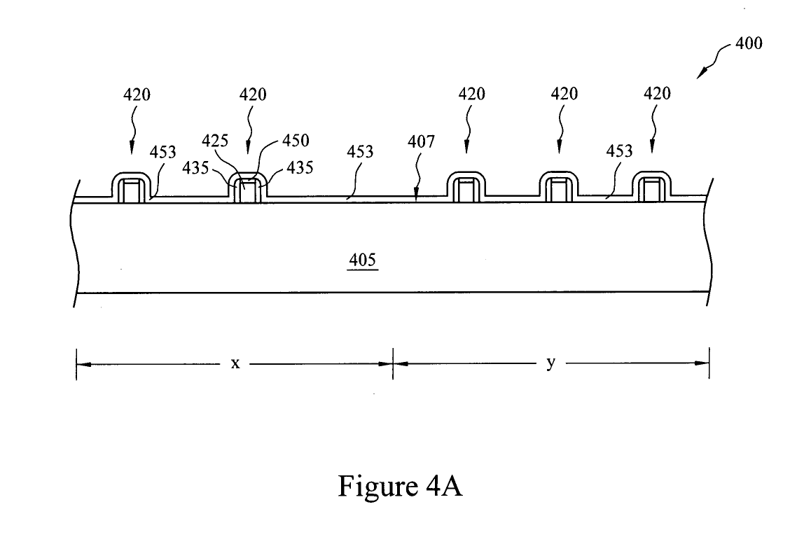

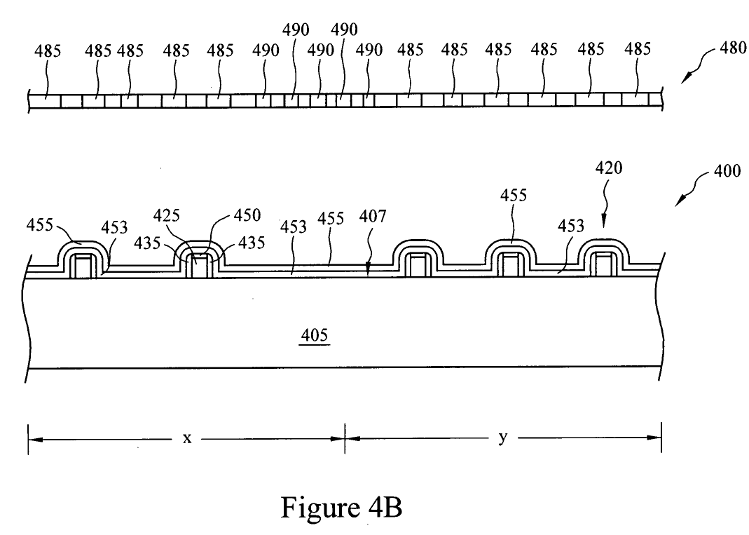

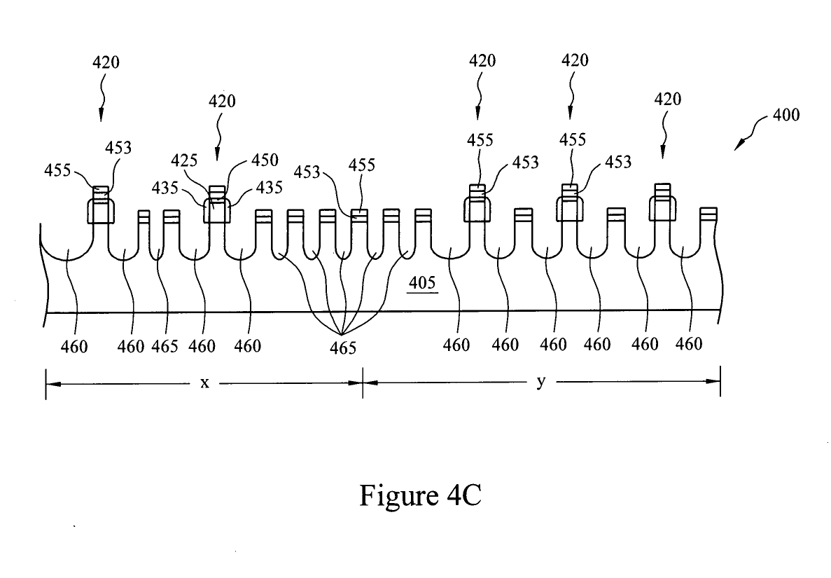

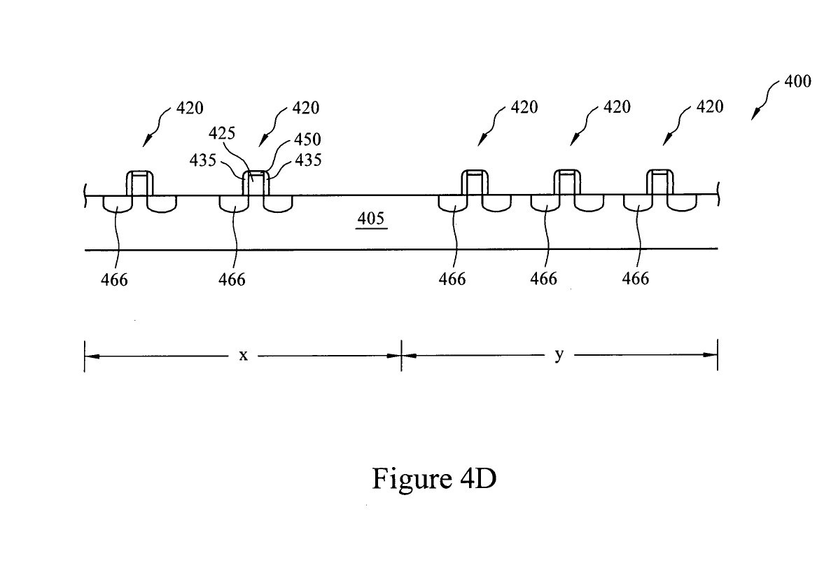

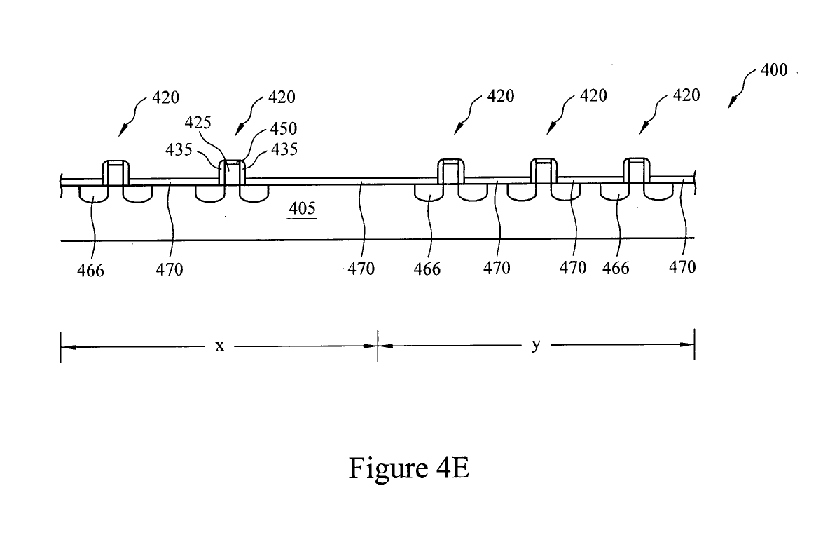

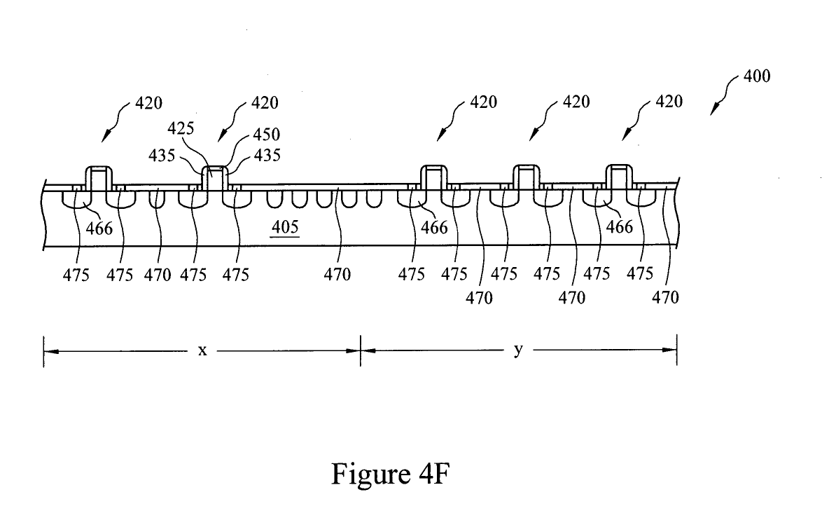

FIGS. 4A through 4F are cross-sectional representations illustrating the semiconductor device 400 at various stages of fabrication according to an embodiment of the present invention. The process begins with the provision of a suitable silicon-wafer substrate 405, populated with a plurality of gate structures 420 (other suitable substrate materials may, of course, be used as well). In this embodiment, prior to lithography an OX/SiN layer 453 is deposited over the surface 407 of substrate 405. This stage of the fabrication is illustrated in FIG. 4A. OX/SiN layer 453 may, for example, be formed of silicon dioxide (SiO₂) or silicon nitride (SiN).

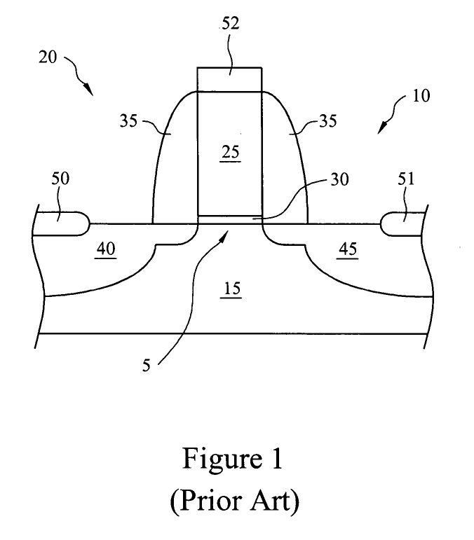

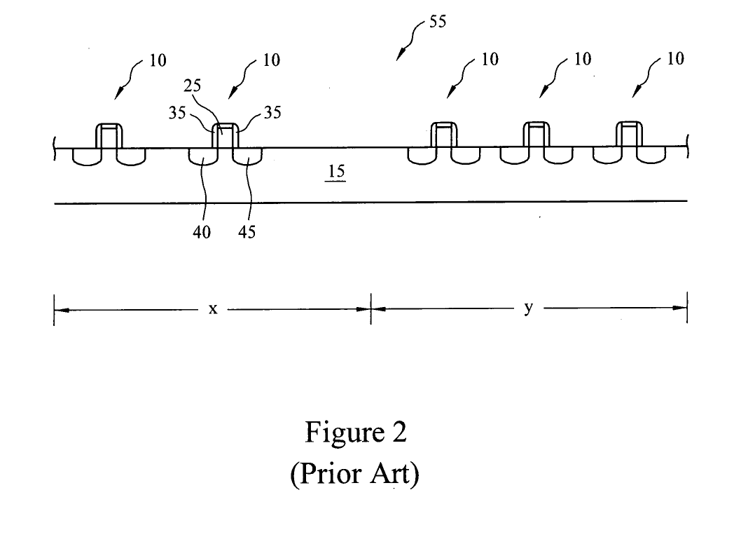

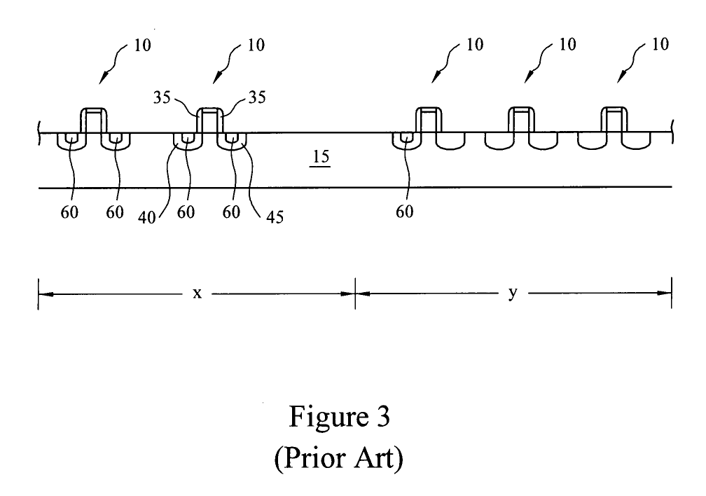

Each of the gate structures shown in FIGS. 4A through 4F are similar in construction though not necessarily identical to the analogous devices shown in FIGS. 1 through 3. As with FIGS. 2 and 3, the component parts of gate structure 420 are labeled with reference numbers on only one such gate structure, the others for convenience being considered substantially identical. Similar to the transistor 10, illustrated in FIG. 1, transistor 420 includes a gate electrode 425. At the top of gate electrode 425 is an electrical contact 450. Spacers 435 are disposed on either side of gate electrode 425. The same transistor distribution of FIGS. 2 and 3 is also used, although many other layout configurations are possible. It should be apparent, however, that the layout of these components is like that of FIGS. 2 and 3, meaning that defects attributable to the local-loading effect is likely to be a risk if selective epitaxial growth (SEG) is undertaken. In the embodiment of FIGS. 4A through 4F, this process is to be employed.

As illustrated in FIG. 4B, a photoresist layer 455 is applied to the upper surface 407 of the wafer substrate 405. Photoresist, or simply resist, is a photosensitive material that may be patterned as part of a fabrication process known as photolithography. Photoresist may also be applied as a decal (not shown) having a series of openings already patterned into it. In the embodiment of FIGS. 4A through 4F, however, an optical mask is provided (though not shown), the mask having a series of openings (or transparent or semitransparent areas) to allow the passage of light from a light source to certain areas of the photoresist. These areas are determined in accordance with the method of the present invention.

In order to implement a preferred embodiment of the present invention, it is determined from the layout of components on the wafer surface (or on some related consideration), where there may be a risk of local-loading-effect defects. These are then mitigated by the development and implementation of a dummy pattern implementation. The term “dummy pattern” refers to a collection of areas selected for epitaxial growth in addition to those actually required by the design layout. For example, in FIG. 4B it should be apparent that there are some regions that are less populated than others. Specifically, the region Y will require the growth of relatively more source and drain structures through selective epitaxy in order to complete the transistors in that region. Region X, on the other hand, has fewer structures and will not require as many.

Whether a dummy pattern is necessary at all, and if so, how it will be configured, is determined on a design-by-design basis according to pre-determined design criteria. But in general, the dummy pattern will be formulated to populate the epitaxial growth regions more evenly with respect to each other. Other factors may also be taken into account. In the embodiment of FIGS. 4A through 4F, the dummy pattern is implemented by altering the mask 480 design so that light from the light source illuminated the resist portions associated with the dummy pattern as well as with the source and drain regions. As can be seen in FIG. 4B, mask 480, shown in cross-section, forms a series of openings through which light will pass when photolithography is performed. In another embodiment (not shown) transparent or translucent regions may be used instead of some or all of the openings. The openings in mask 480 include layout openings 485, which will facilitate the formation of recesses for actual design-layout features. Dummy openings 490 will facilitate formation of the dummy-pattern recesses according to the present invention.

Selectively illuminating the photoresist layer 455 through the optical mask and developing the illuminated resist causes some areas to become harder to remove with a selected solvent than others. Following illumination and development, the selected solvent (or other agent) is used to create the resist pattern. A dry etching step is then performed, etching away the substrate to create recesses 460 and recesses 465. These recesses are illustrated in FIG. 4C. As should be apparent, the recesses are formed by the etching in areas where the resist has previously been removed, the etching agent being selected to achieve this affect. The recesses 460 are formed for formation of the source and drain regions according to the original design, and recesses 465 are those that are created as part of the dummy-pattern process according to this embodiment of the present invention.

In the embodiment of FIGS. 4A though 4F, the remaining resist structures are then removed, and SEG used to create epitaxial regions 466 in the previously formed recesses 460 and 465, as illustrated in FIG. 4D. The epitaxial regions 466 may be formed of doped silicon or a silicon-germanium (SiGe) alloy. Carbon may also form or be included in the epitaxial-region material, for example using SiC. In one embodiment, an epitaxial material according to the formula Si_{1-X} Geₓ may be used. Different materials may, in some instances, be used for different epitaxial regions, although this is not typical. The epitaxial regions 466 formed in recesses 460 and 465 may, for one example, be formed on the substrate using an ultra-high vacuum chemical-vapor deposition (UHV-CVD) process. Other processes known or developed in the art may be used as well.

As should be apparent from a comparison between FIG. 4D and FIG. 3, described above, the use of a dummy pattern for epitaxial growth reduces the ratio of un-populated to populated regions of semiconductor device 400 and results in superior formation of the source and drain regions. As shown in FIG. 4E, an insulating layer 470, such as one of SiO₂, is then deposited to isolate the newly filled recesses. In another embodiment of the present invention, SiN may be used as the insulator layer. Finally, the recesses 465 that are part of the dummy pattern will remain isolated, while conventional methods are used to form posts 475 or other conductors as contact structures for the sources and drain regions formed in recesses 460. FIG. 4F illustrates the semiconductor device 400 at this stage of fabrication.

Although the present invention and its advantages have been described in detail, it should be understood that various changes, substitutions and alterations can be made herein without departing from the spirit and scope of the invention as defined by the appended claims. For example, method steps may be performed simultaneously or in series, or in any different, logically-permissible order. Equivalent processes or materials, other than those mentioned, may also be utilized without departing from the spirit of the invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of making a semiconductor device, comprising the steps of:
providing a semiconductor substrate, the substrate having an upper surface;
forming a first recess in the upper surface of the substrate;
forming at least a second recess in the upper surface of the substrate;
growing a first epitaxial region in the first recess; and
growing a second epitaxial region in the second recess;
wherein the second epitaxial region is electrically isolated so as to function as a dummy structure during the fabrication process.

2. The method as set forth in claim 1, further comprising forming an insulating layer over the second epitaxial region.

3. The method as set forth in claim 1, wherein each of the first epitaxial region and the second epitaxial region comprise at least one of germanium and carbon.

4. The method as set forth in claim 3, wherein each of the first epitaxial region and the second epitaxial region further comprise silicon.

5. The method as set forth in claim 4, wherein each of the first epitaxial region and second epitaxial layer consist essentially of germanium and silicon.

6. The method as set forth in claim 4, wherein each of the first epitaxial region and second epitaxial region consist essentially of carbon and silicon.

7. The method of claim 1, wherein each of the first epitaxial region and second epitaxial layer comprise Si1-xGex, wherein x and y are variables having a value between 0 and 1.

8. The method of claim 1, wherein each of the first epitaxial region and second epitaxial layer comprise SiC.

9. The method as set forth in claim 1, wherein each of the steps of forming a first recess and forming a second recess comprise selectively etching the substrate using a wet etchant.

10. The method as set forth in claim 1, wherein each of the steps of forming a first recess and forming a second recess comprise the steps of:
depositing a photoresist layer over the upper surface of the semiconductor substrate;
patterning the photoresist to provide openings therethrough;
and selectively etching the semiconductor substrate through the openings in the photoresist layer using a wet etchant.

11. The method as set forth in claim 10, further comprising the step of removing the patterned photoresist; wherein each of the first epitaxial region and the second epitaxial region comprise at least one of germanium and carbon.

12. The method as set forth in claim 1, further comprising the step of forming a gate over the surface of the semiconductor substrate, wherein the first recess is disposed adjacent the gate.

13. The method as set forth in claim 12, further comprising the steps of forming a third recess and growing a third epitaxial region filling the third recess;
wherein the gate is adjacent the third recess such that the first epitaxial region provides a source and a third epitaxial region provides a drain.

14. The method as set forth in claim 13, further comprising the steps of forming a first post connected to the source; and forming a second post connected to the drain.

15. The method as set forth in claim 1, wherein the at least second recess comprises a plurality of recesses for forming dummy structures, and further comprising the step of growing an epitaxial region in each of the plurality of recesses for forming dummy structures.

16. The method as set forth in claim 1, further comprising the step of depositing a photoresist layer by one of spinning on a photoresist layer and adhering a photoresist decal to the upper surface of the semiconductor substrate.

17. The method as set forth in claim 1, further comprising the steps of forming a first metal layer electrically connected to the first epitaxial region, and forming an insulating layer over the second epitaxial region.

18. The method as set forth in claim 1, further comprising the steps of forming a third recess in the upper surface of the semiconductor substrate, and growing a third epitaxial region in the third recess, the third epitaxial region comprising at least one of germanium and carbon, and thereafter forming a gate over the upper surface of the substrate and so that the first epitaxial region provides a source and the third epitaxial region provides a drain.

19. The method as set forth in claim 18, further comprising forming a first electrically conductive layer comprising a metal so that the first electrically conductive layer is connected to the first epitaxial region, forming a second electrically conductive layer comprising a metal so that the second electrically conductive layer is connected to the third epitaxial region.

20. A semiconductor device, comprising:
a semiconductor substrate;
a first epitaxial region formed in the substrate, and a first electrically conductive layer comprising a metal connected to the first epitaxial region; and
a plurality of dummy epitaxial regions formed in the substrate and an insulating layer overlying the plurality of dummy epitaxial regions;
wherein each of the first epitaxial region and each of the plurality of dummy epitaxial regions comprise at least one of germanium and carbon.
